(19) United States
(12) Patent Application Publication
(10) Pub. No.: US 2023/0394209 A1
(43) Pub. Date: Dec. 7, 2023

(54) FUNCTIONAL VERIFICATION FLOW OF OBFUSCATED DESIGNS FOR CIRCUITS

(71) Applicant: University of Florida Research Foundation, Incorporated, Gainesville, FL (US)

(72) Inventors: Swarup BHUNIA, Gainesville, FL (US); Sandip RAY, Gainesville, FL (US); Moshiur RAHMAN, Gainesville, FL (US); Maneesh MERUGU, Gainesville, FL (US)

(21) Appl. No.: 18/327,296

(22) Filed: Jun. 1, 2023

Related U.S. Application Data
(60) Provisional application No. 63/348,090, filed on Jun. 2, 2022.

(51) Int. Cl. G06F 30/33; G06F 30/327; G06F 30/392

(52) U.S. Cl. CPC G06F 30/33; G06F 30/327; G06F 30/392

(57) ABSTRACT

Various embodiments of the present disclosure provide functional verification flow of obfuscated designs for circuits. In one example, an embodiment provides for applying an input sequence to an obfuscated design for an integrated circuit that is formatted in a hardware description language, applying the input sequence to an original design for the integrated circuit that is formatted in the hardware description language, and comparing respective outputs provided by the obfuscated design and the original design to determine functional correctness of the obfuscated design.

### CROSS REFERENCE TO RELATED APPLICATIONS

This application claims priority to U.S. Appl. No. 63/348,090 filed Jun. 2, 2022, the contents of which are incorporated herein in its entirety by reference.

### GOVERNMENT SUPPORT

This invention was made with government support under HR0011-21-3-0001 awarded by US DEPARTMENT OF DEFENSE DARPA. The government has certain rights in the invention.

### TECHNICAL FIELD

The present application relates to the technical field of integrated circuits. In particular, the invention relates to hardware obfuscation associated with integrated circuits

### BACKGROUND

Hardware cores are commonly employed in the semiconductor industry. Furthermore, a single System on Chip (SoC) generally comprises one or more third-party semiconductor cores such as one or more hardware Intellectual Property (IP) cores. A hardware IP core is typically comprised of Register Transfer Level (RTL) source code and/or one or more gate-level netlists. However, hardware IP cores are generally vulnerable to security concerns such as IP piracy, counterfeiting, reverse engineering, etc. As such, an IP protection technique such as, for example, an authentication technique or an obfuscation technique, can be employed to provide IP protection. Authentication techniques generally rely on insertion of a unique signature (e.g., watermark) to prove ownership of a hardware IP core. Obfuscation techniques, on the other hand, generally rely on preventing an attacker from black-box usage of a hardware IP core and/or understanding a design-intent of a hardware IP core, thereby preventing an unauthorized third-party from gaining access to the hardware IP core or replicating a design of the hardware IP core.

### SUMMARY

In general, embodiments of the present invention provide methods, apparatus, systems, computing devices, computing entities, and/or the like for functional verification flow of obfuscated designs for circuits. The details of some embodiments of the subject matter described in this specification are set forth in the accompanying drawings and the description below. Other features, aspects, and advantages of the subject matter will become apparent from the description, the drawings, and the claims.

In an embodiment, a method for providing a functional verification flow of obfuscated designs for circuits is provided. The method provides for applying an input sequence to an obfuscated design for an integrated circuit that is formatted in a hardware description language, applying the input sequence to an original design for the integrated circuit that is formatted in the hardware description language, and/or comparing respective outputs provided by the obfuscated design and the original design to determine functional correctness of the obfuscated design.

In another embodiment, an apparatus for providing a functional verification flow of obfuscated designs for circuits is provided. The apparatus comprises at least one processor and at least one memory including program code. The at least one memory and the program code is configured to, with the at least one processor, cause the apparatus to apply an input sequence to an obfuscated design for an integrated circuit that is formatted in a hardware description language, apply the input sequence to an original design for the integrated circuit that is formatted in the hardware description language, and/or compare respective outputs provided by the obfuscated design and the original design to determine functional correctness of the obfuscated design.

In yet another embodiment, a non-transitory computer storage medium comprising instructions for providing a functional verification flow of obfuscated designs for circuits is provided. The instructions are configured to cause one or more processors to at least perform operations configured to apply an input sequence to an obfuscated design for an integrated circuit that is formatted in a hardware description language, apply the input sequence to an original design for the integrated circuit that is formatted in the hardware description language, and/or compare respective outputs provided by the obfuscated design and the original design to determine functional correctness of the obfuscated design.

### BRIEF DESCRIPTION OF THE DRAWINGS

Reference will now be made to the accompanying drawings, which are not necessarily drawn to scale, and wherein:

FIG. 1 provides an example verification flow, according to one or more embodiments of the present disclosure;

FIG. 2 illustrates an exemplary formal verification framework, according to one or more embodiments of the present disclosure;

FIG. 3 illustrates an exemplary algorithm that provides for formal equivalence verification of obfuscated designs, according to one or more embodiments of the present disclosure;

FIG. 4 illustrates a flowchart of a method for providing a functional verification flow of obfuscated designs for circuits according to one or more embodiments of the present disclosure; and

FIG. 5 illustrates a schematic of a computing entity that may be used in conjunction with one or more embodiments of the present disclosure.

### DETAILED DESCRIPTION

The present disclosure more fully describes various embodiments with reference to the accompanying drawings. It should be understood that some, but not all, embodiments are shown and described herein. Indeed, the embodiments may take many different forms, and, accordingly, this disclosure should not be construed as limited to the embodiments set forth herein. Rather, these embodiments are provided so that this disclosure will satisfy applicable legal requirements. Like numbers refer to like elements throughout.

As discussed above, hardware cores are commonly employed in the semiconductor industry. Furthermore, a single System on Chip (SoC) generally comprises one or more third-party semiconductor cores such as one or more hardware Intellectual Property (IP) cores. A hardware IP core is typically comprised of Register Transfer Level (RTL) source code and/or one or more gate-level netlists. However, hardware IP cores are generally vulnerable to security concerns such as IP piracy, counterfeiting, reverse engineering, etc. As such, an IP protection technique such as, for example, an authentication technique or an obfuscation technique, can be employed to provide IP protection. Authentication techniques generally rely on insertion of a unique signature (e.g., watermark) to prove ownership of a hardware IP core. Obfuscation techniques, on the other hand, generally rely on preventing an attacker from black-box usage of a hardware IP core and/or understanding a design-intent of a hardware IP core, thereby preventing an unauthorized third-party from gaining access to the hardware IP core or replicating a design of the hardware IP core.

Hardware obfuscation is a technique to protect hardware IP cores against piracy attacks and/or other security vulnerabilities. Hardware obfuscation modifies structure and/or functionality of a design of a hardware IP core such that it becomes difficult to reproduce the structure and/or functionality of the original design of the hardware IP core from the modified design of the hardware IP core. As such, hardware obfuscation can be employed to protect hardware IP cores against IP theft, reverse engineering, counterfeiting, piracy attacks and/or other security vulnerabilities. Hardware obfuscation often employs the addition of obfuscation logic to an original design of a hardware IP core to modify the structure and/or functionality of the original design of the hardware IP core. Accordingly, the hardware IP core only performs as originally intended after a specific input sequence has been provided to the modified design of the hardware IP core. The input sequence can behave, for example, as a key such that the original design is locked until the key (e.g., the input sequence) is applied to the original design.

Obfuscation techniques have been evolving over the past years due to advancement in technologies. Certain obfuscation techniques (e.g., a functional obfuscation technique, etc.) are applied to an early stage of a life cycle of a hardware IP core. For example, functional obfuscation techniques (e.g., logic locking techniques) are applied to Register-Transfer Level (RTL) or gate-level netlists. Alternatively, certain obfuscation techniques (e.g., a physical obfuscation technique, etc.) are applied in a fabrication stage of a hardware IP core. For example, physical obfuscation techniques are post-silicon measures that are applied to a basic structure of logic elements of an integrated circuit. However, traditional obfuscation techniques do not provide an ability to verify functional correctness of obfuscated designs of hardware IP cores. For example, even though obfuscation of a hardware IP core makes it computationally impossible for a third-party manufacturer to determine an unlocking sequence for the obfuscation, it is desirable to determine whether the obfuscated design is indeed the same as the original design of the hardware IP core.

To address these and/or other issues, various embodiments described herein relate to a functional verification flow of obfuscated designs for circuits. For example, functional correctness of obfuscated designs for circuits can be verified according to various embodiments described herein. In various embodiments, mathematical assurance and/or certification can be provided for the functional correctness of obfuscated designs for circuits. In various embodiments, a novel formal verification framework for verification of logic locked and/or state space obfuscated designs of IP hardware cores is provided. In various embodiments, the formal verification framework can verify that an obfuscated design of an IP hardware core behaves exactly the same as an original design of the IP hardware core. The formal verification framework can also ensure that the obfuscated design is free from any bugs that might have been introduced during the transformation of the original design. In various embodiments, the formal verification framework can employ one or more formal engines and/or mathematical models along with a set of formal assertion assumptions to identify whether a modified design and an original design are equivalent.

In various embodiments, an assurance gap between IP designers and SoC integrators or manufacturers can be provided. For example, a design of an SoC with one or more hardware IP cores can be securely transferred between a designer and manufacturer. In various embodiments, a certification of an obfuscated design is provided to ensure that the obfuscated design is functionally equivalent to the original design in all possible scenarios. The certification of the obfuscated design can employ, for example, a key sequence. For example, a design and/or functionality of an SoC with one or more hardware IP cores can be obfuscated such that the SoC only functions correctly based on a correct key that is configured as an activation package for the SoC. Additionally, the design of the SoC can be securely transferred to a foundry for manufacturing such that the foundry can transfer the design back to the IP designer. The IP designer can further unlock the design of the SoC using the correct key (e.g., the activation package) to allow the SoC to behave as originally designed. As such, improved performance and/or security for a SoC can be provided.

In various embodiments, in response to a determination that a bug is present in the obfuscation methodology that makes an obfuscated design and an original design inequivalent, a counterexample (e.g., an error scenario) can be provided to identify the bug. Accordingly, a standard formal equivalence checking methodology can be provided for functional correctness of obfuscated designs. Additionally, existing formal engines and/or dynamic assertion monitors can be integrated into a novel certification flow that enables equivalence verification of obfuscated designs. A mathematical guarantee for functional correctness of obfuscated designs can also be provided.

In various embodiments, enhanced security for a circuit can be provided by functional verification flow of obfuscated designs for the circuit, as disclosed herein. The enhanced security of the circuit can also provide a more advanced circuit and/or improved performance for the circuit. By providing functional verification flow of obfuscated designs for the circuit, protection of IP cores and/or other security critical assets of the circuit against targeted attacks and/or other security vulnerabilities can also be provided.

As disclosed herein, the term ‘obfuscation’ may be used interchangeably to represent electronic hardware obfuscation or logic locking techniques.

Additionally, as disclosed herein, RTL source code can model an integrated circuit (e.g., an SoC, a semiconductor core, etc.) based on flow of signals between hardware components and/or logical operations associated with the signals. For example, a hardware description language can be employed to implement RTL source code, which provides a high-level description of an integrated circuit.

### A. EXEMPLARY FUNCTIONAL VERIFICATION FLOW OF OBFUSCATED DESIGNS FOR CIRCUITS

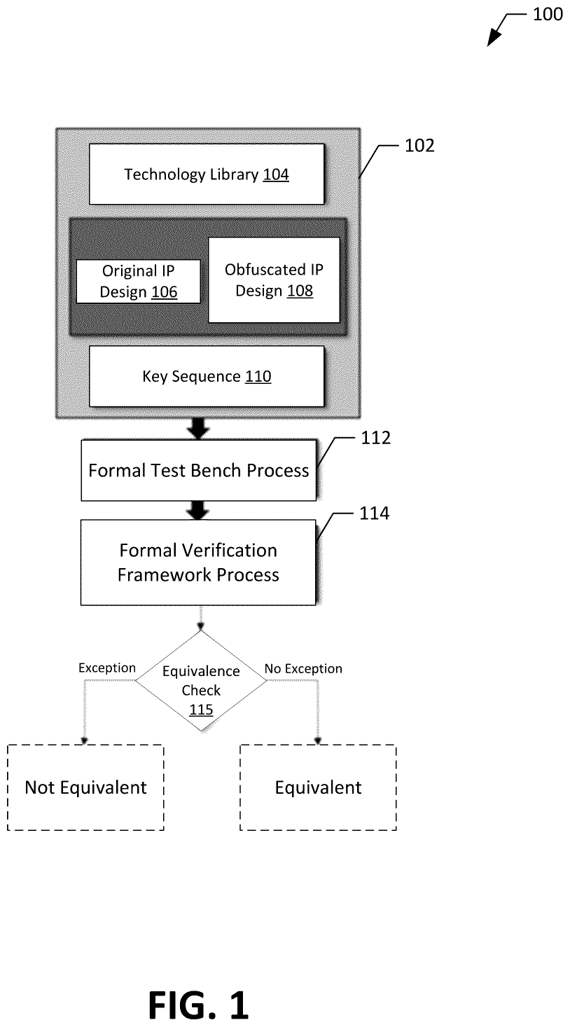

According to various embodiments, a functional verification flow of obfuscated designs for circuits is provided. For example, a verification tool for obfuscated designs can be provided for equivalence checking of the obfuscated designs. An example verification flow 100 is shown in FIG. 1, according to one or more embodiments of the present disclosure. The verification flow 100 includes an obfuscation process 102. The obfuscation process 102 can be, for example, a design transformation process for a circuit. The circuit can be an integrated circuit, a hardware IP core, an SoC that includes one or more hardware IP cores, a Network-on-Chip (NoC), or another type of circuit. According to various embodiments, the obfuscation process 102 can employ an RTL-based mechanism to provide an obfuscated design. Moreover, according to various embodiments, the obfuscation process 102 can be related to functional obfuscation. In various embodiments, the obfuscation process 102 can employ a technology library 104 to generate an original IP design 106 and/or an obfuscated IP design 108 for the circuit. The technology library 104 can include a collection of logic gates and/or logic gate characteristics that can be employed to generate the original IP design 106 and/or the obfuscated IP design 108 for the circuit. Additionally, in various embodiments, the obfuscation process 102 can generate a key sequence 110. The key sequence 110 can be an activation package configured to unlock the obfuscated IP design 108 to allow the obfuscated IP design 108 to behave as the original IP design 106. In certain embodiments, the key sequence 110 can be a set of programmable bits and/or a set of configurable parameters to control one or more circuit elements (e.g., one or more registers, one or more multiplexers, etc.) of the obfuscated IP design 108.

In certain embodiments, the obfuscation process 102 can employ combination locking obfuscation to generate the obfuscated IP design 108 and/or the key sequence 110 for the circuit. Alternatively, the obfuscation process 102 can employ sequential locking obfuscation to generate the obfuscated IP design 108 and/or the key sequence 110 for the circuit. However, it is to be appreciated that, in certain embodiments, the obfuscation process 102 can employ a different type of obfuscation technique to generate the obfuscated IP design 108 and/or the key sequence 110 for the circuit. For example, in certain embodiments, the key sequence 110 can be configured as key inputs associated with a set of extra input ports that are added to the original IP design 106 where each key input holds a single static key bit. Alternatively, in certain embodiments, the key sequence 110 can be configured as key values for functional input ports of the original IP design 106.

In certain embodiments, the obfuscated IP design 108 can be an obfuscated SoC design or an obfuscated NoC design. In certain embodiments, the obfuscation process 102 can include systematically replacing one or more connections of the original IP design 106 with respective switches that can be programmed after fabrication. The respective switches can include a specific set of state elements, only one of which may correspond to an original topology of the original IP design 106. The switch configuration (e.g., specific set of state elements) can correspond to the key sequence 110. In various embodiments, the obfuscation process 102 can replace static routing tables of the original IP design 106 with configurable logic tables. Additionally or alternatively, the obfuscation process 102 can replace static fabric connections of the original IP design 106 with a combination of programmable multiplexers (MUXs) related to switch configurations. For example, an interconnect topology of the original IP design 106 can be transformed through the obfuscation process 102 that systematically redacts connection structures using programmable MUXs. The programmable MUXs can be controlled by programmable registers (e.g., programmable key registers)

The verification flow 100 also includes a formal test bench process 112 and/or a formal verification framework process 114. The formal test bench process 112 can be employed to test the obfuscated IP design 108 as a device under test. The formal verification framework process 114 can be employed to verify equivalence of the obfuscated IP design 108 as compared to the original IP design 106. In various embodiments, the formal verification framework process 114 applies the key sequence 110 to the original IP design 106 and the obfuscated IP design 108 to determine whether the original IP design 106 and the obfuscated IP design 108 provide the same output in response to being provided the same input. A deviation with respect to the outputs provided by the original IP design 106 and the obfuscated IP design 108 can result in an equivalence exception leading to a counterexample. However, a determination that the outputs provided by the original IP design 106 and the obfuscated IP design 108 are equal can result in an equivalent verification between the original IP design 106 and the obfuscated IP design 108.

In various embodiments, the formal verification framework process 114 performs an equivalence check 115 to verify that the original IP design 106 and the obfuscated IP design 108 are equivalent. For example, during the equivalence check 115, the obfuscated IP design 108 can be considered the device under test and the original IP design 106 can be considered the reference design (e.g., the golden design). In certain embodiments, the obfuscated IP design 108 can be an RTL source code under test, and the original IP design 106 can be a reference RTL source code. In various embodiments, the equivalence check 115 can compare output of the original IP design 106 to output of the obfuscated IP design 108. In response to a determination by the equivalence check 115 that output of the original IP design 106 does not match output of the obfuscated IP design 108, an exception can be raised (e.g., Exception) and it can be determined that the obfuscated IP design 108 and the original IP design 106 are not equivalent.

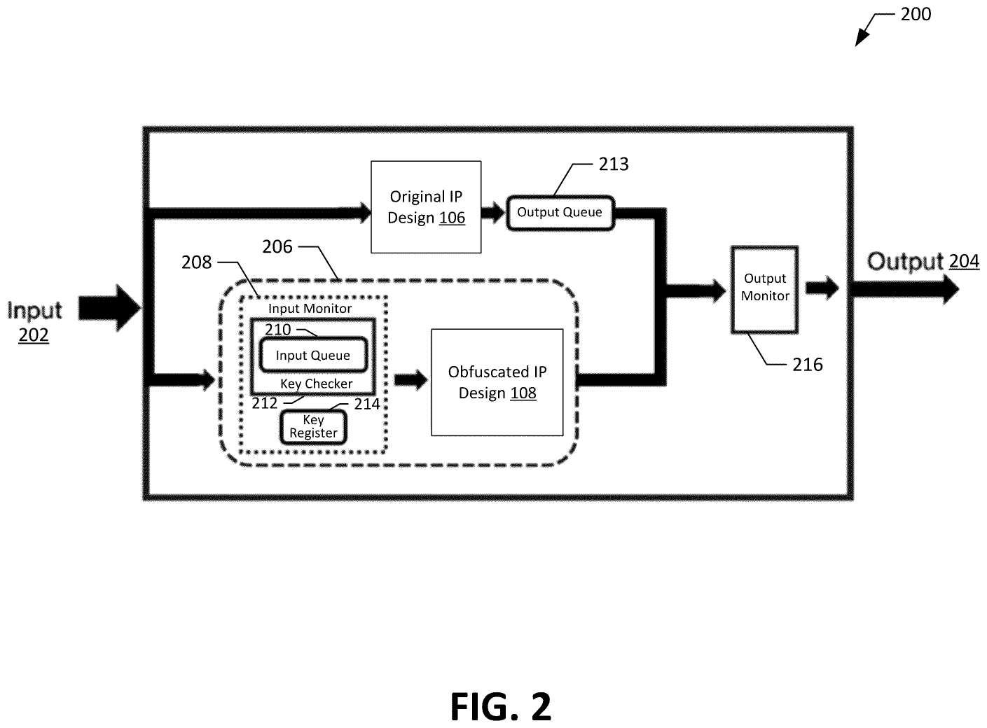

FIG. 2 illustrates a formal verification framework 200 according to one or more embodiments of the present disclosure. In one or more embodiments, an input 202 is applied to the original IP design 106 and the obfuscated IP design 108. The input 202 can be, for example, an input sequence (e.g., a binary sequence, a bit sequence, etc.). In certain embodiments, the input 202 can correspond to the key sequence 110 such that the obfuscated IP design 108 behaves exactly the same as an original IP design 106. For example, in response to the input 202 corresponding to the key sequence 110, the obfuscated IP design 108 and the original IP design 106 can provide the same output. However, in certain embodiments when the input 202 does not correspond to the key sequence 110, the obfuscated IP design 108 can behave differently than the original IP design 106 such that the obfuscated IP design 108 and the original IP design 106 provide different outputs.

In various embodiments, the original IP design 106 can correspond to an RTL source code that models a circuit based on flow of signals between hardware components and/or logical operations associated with the signals. For example, the original IP design 106 can be configured as a hardware description language that provides a high-level description of the circuit. The circuit can be an integrated circuit or another type of circuit that includes one or more IP cores and/or one or more switches.

Additionally, the obfuscated IP design 108 can correspond to an obfuscated RTL source code where the RTL source code associated with the original IP design 106 is transformed into the obfuscated RTL source code via the obfuscation process 102. For example, the obfuscated RTL source code can be configured as a transformed hardware description language that provides a transformed description of the circuit. In various embodiments, the obfuscated RTL source code can be configured to describe one or more IP cores, one or more transformed switches, and/or one or more switches that have not undergone obfuscation. The one or more transformed switches can be obfuscated versions of the one or more switches included in the original IP design 106.

In one or more embodiments, the obfuscation process 102 can transform the RTL source code associated with the original IP design 106 into the obfuscated RTL source code associated with the obfuscated IP design 108 via routing table obfuscation and/or topology obfuscation. In one or more embodiments, the routing table obfuscation can be configured to replace one or more static routing tables related to the original IP design 106 with one or more configurable logic tables for the obfuscated IP design 108. In various embodiments, the routing table obfuscation can be configured to replace routing logic for the original IP design 106 with respective configurable tables for the obfuscated IP design 108. For example, the routing table obfuscation can replace routing table metadata for the original IP design 106 with configurable table entries that can be configured (e.g., burnt) into configurable tables after manufacturing of the circuit. Configurable parameters for the routing (e.g., configuration parameters for the configurable tables) can be configured such that routing occurs through (e.g., routing occurs only through) configuration provided by the configurable parameters. In one or more embodiments, the topology obfuscation can be configured to replace static fabric connections related to the original IP design 106 with a combination of programmable multiplexers for the obfuscated IP design 108. In various embodiments, the topology obfuscation can provide system-level design transformation with respect to the original IP design 106.

In various embodiments, the input 202 is an input sequence that is applied to the obfuscated IP design 108 for the circuit. In various embodiments, the obfuscated IP design 108 can be formatted in a hardware description language. In various embodiments, the input 202 (e.g., the input sequence) can correspond to a potential key sequence or the key sequence 110 generated during obfuscation of the original IP design 106 via the obfuscation process 102. Additionally, the input 202 (e.g., the input sequence) can be applied to the original IP design 106 for the circuit. In various embodiments, the original IP design 106 can also be formatted in the hardware description language. The formal verification framework 200 can then compare respective outputs provided by the obfuscated IP design 108 and the original IP design 106 to determine functional correctness of the obfuscated IP design 108.

The input 202 (e.g., the input sequence) can be applied to the obfuscated IP design 108 by providing the input 202 to a key checker 212 that compares the input 202 to data stored in a key register 214. The data stored in the key register 214 can be a predetermined key sequence for the obfuscated IP design 108 such as, for example, the key sequence 110. In one or more embodiments, a key loading sequence portion 206 of the formal verification framework 200 can include an input monitor 208 to align the obfuscated IP design 108 to the original IP design 106 and/or to account for timing mismatch between the obfuscated IP design 108 to the original IP design 106 based on the input 202. The input monitor 208 can include the key checker 212 and the key register 214. The key checker 212 can employ an input queue 210 to enqueue the input 202 being processed by the obfuscated IP design 108 in parallel to the input 202 being processed by the original IP design 106. The key register 214 can be configured to store the key sequence 110, and the key checker 212 can employ data stored in the key register 214 to compare the input 202 to the key sequence 110. For example, the key checker 212 can generate a key error value in response to a determination that the input 202 does not correspond to the key sequence 110. In response to the input 202 not corresponding to the key sequence 110, the key checker 212 can additionally flag the key error and/or increment a key error count. In certain embodiments, application of the input 202 to the obfuscated IP design 108 can be withheld in response to a determination that the input 202 does not correspond to the key sequence 110. Additionally or alternatively, application of the input 202 to the obfuscated IP design 108 can be withheld in response to a determination that the key error count corresponds to a key error count threshold and/or that the key error value corresponds to a predefined key error value. However, in response to a determination that the input 202 corresponds to the key sequence 110, the input 202 can be applied to the obfuscated IP design 108.

In various embodiments, an output value provided by the original IP design 106 in response to the input 202 being applied to the original IP design 106 can be stored in an output queue 213. For example, the output value provided by the original IP design 106 can be stored in the output queue 213 while the input 202 is being processed by the obfuscated IP design 108. In various embodiments, the output queue 213 can be employed to align the original IP design 106 to the obfuscated IP design 108 and/or to account for timing mismatch between the original IP design 106 to the obfuscated IP design 108 based on the input 202.

The formal verification framework 200 can also include an output monitor 216 configured for equivalence checking between an output value provided by the original IP design 106 and an output value provided by the obfuscated IP design 108 in response to the input 202. In various embodiments, the output monitor 216 can be configured as a miter circuit. The miter circuit can be configured to encode an equivalence check of the obfuscated IP design 108 and the original IP design 106. For example, the miter circuit can be a combinational circuit that outputs an equivalent value (e.g., an equivalent indication) in response to a determination that output from the obfuscated IP design 108 matches output from the original IP design 106. However, the miter circuit can output a not equivalent value (e.g., a not equivalent indication) in response to a determination that output from the obfuscated IP design 108 does not match output from the original IP design 106. In one or more embodiments, the output monitor 216 can compare an output value of the obfuscated IP design 108 with an output value of the original IP design 106. In certain embodiments, the output monitor 216 can compare an output value of the obfuscated IP design 108 with an output value of the original IP design 106 dequeued from the output queue 213. In response to a determination that the output value of the obfuscated IP design 108 corresponds to the output value of the original IP design 106, an output 204 of the output monitor 216 can correspond to a first value indicative of formal verification of the obfuscated IP design 108. However, in response to a determination that the output value of the obfuscated IP design 108 does not correspond to the output value of the original IP design 106, the output 204 of the output monitor 216 can correspond to a second value indicative of an exception that indicates that obfuscated IP design 108 is not functionally, logically, and/or structurally equivalent to the original IP design 106.

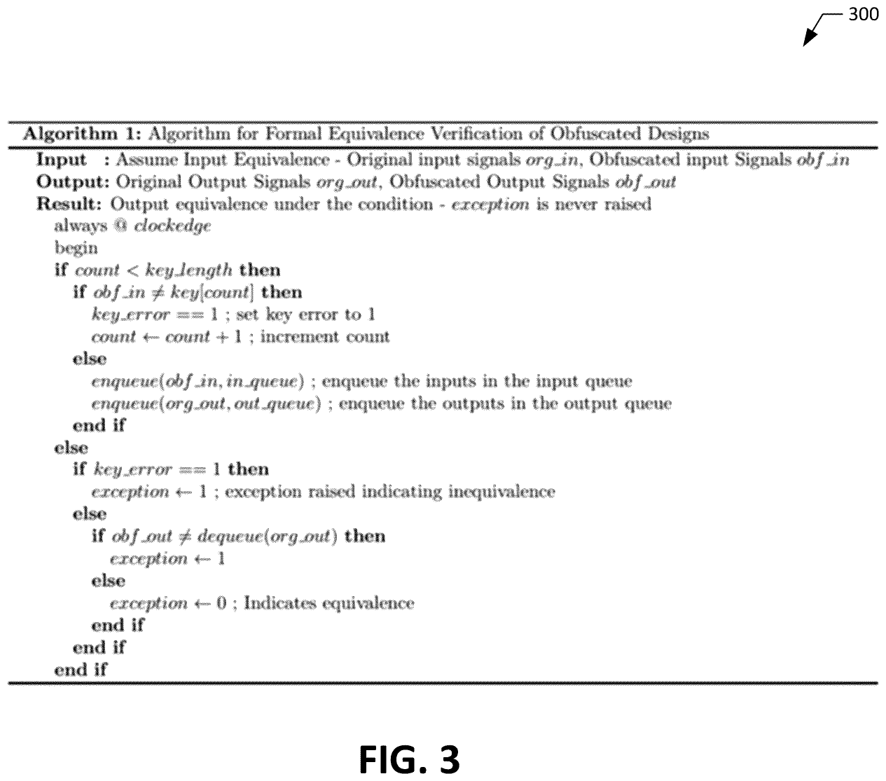

FIG. 3 illustrates an algorithm 300 that provides for formal equivalence verification of obfuscated designs according to one or more embodiments of the present disclosure. In various embodiments, the algorithm 300 can be employed by the formal verification framework process 114 and/or the formal verification framework 200. In various embodiments inputs can be constrained to be equivalent. To achieve this, the same inputs can be applied to both the original and the obfuscated designs. In various embodiments, the inputs can be directly applied to the original design whereas the inputs (org in, obf in) can be enqueued on the side of the obfuscated design using the input queue (in queue). In various embodiments, the input queue can be employed to align the designs and/or to account for timing mismatch between the two designs (e.g., the obfuscated design operates as original only after the key sequence has been appropriately applied). In various embodiments, the key inputs can be driven as the input to the obfuscated design side using a formal verification framework. In various embodiments, key error (signal key error) is asserted to 1 if the key is not applied properly (e.g., the key checker will flag any input other than the key sequence (key count)).

In various embodiments, the outputs of the original design (org out) can be enqueued using an output queue (out queue) while the key loading sequence occurs on the obfuscated design side. As with the input queue, this can provide adjustment for timing disparity of outputs. In various embodiments, an output monitor is configured to check, in sequence, the outputs of the obfuscated design (obf out) with the dequeued outputs from the original design. If the corresponding outputs do not match, an exception is raised. In various embodiments, the formal verification framework can be employed to mathematically verify that the output monitor does not raise an exception. In response to the formal verification framework successfully completing this verification, then it can be determined that the obfuscated design is logically equivalent to the original design. However, if either the key exception or the output exception is raised, the assertion would fail, leading to a counterexample indicating that the designs are not equivalent.

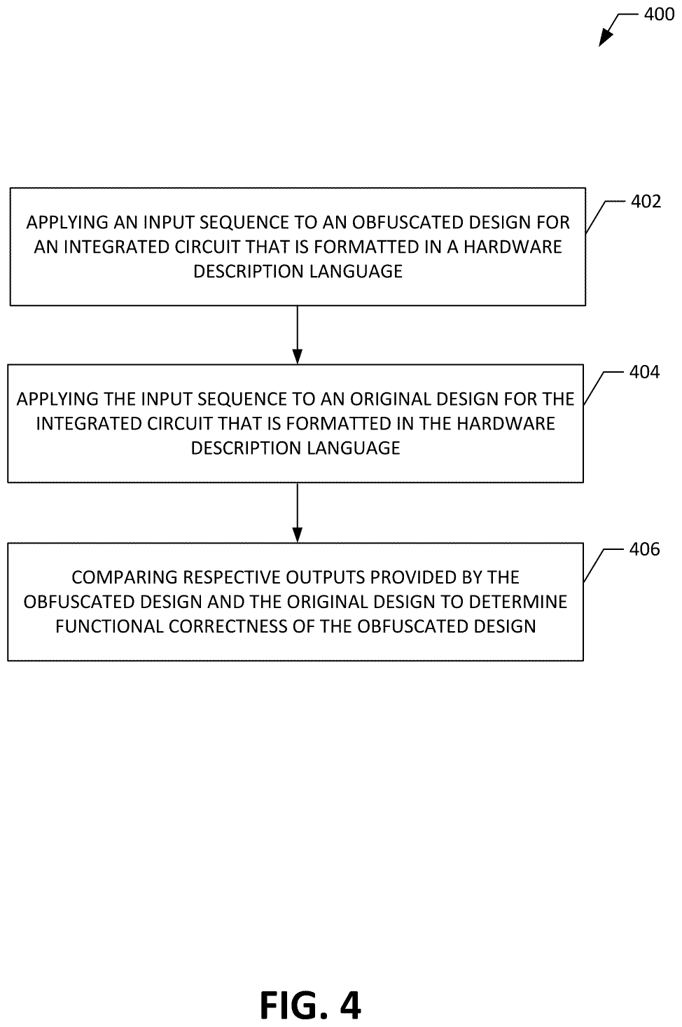

FIG. 4 illustrates a flowchart of a method 400 for providing a functional verification flow of obfuscated designs for circuits according to one or more embodiments of the present disclosure. According to the illustrated embodiment, the method 400 includes a step 402 for applying an input sequence to an obfuscated design for an integrated circuit that is formatted in a hardware description language. In certain embodiments, the input sequence is a potential key sequence generated during obfuscation of the original design. Additionally, the method 400 includes a step 404 for applying the input sequence to an original design for the integrated circuit that is formatted in the hardware description language. The method 400 additionally includes a step 406 for comparing respective outputs provided by the obfuscated design and the original design to determine functional correctness of the obfuscated design.

In certain embodiments, the applying the input sequence to the obfuscated design includes providing the input sequence to a key checker that compares the input sequence to data stored in a key register. In certain embodiments, the method 400 includes applying the input sequence to the obfuscated design in response to a determination that the input sequence corresponds to the data stored in the key register. In certain embodiments, data stored in the key register is a predetermined key sequence generated during an obfuscation process for the obfuscated design. In certain embodiments, the method 400 includes generating a key error value in response to a determination that the input sequence does not correspond to the data stored in the key register. In certain embodiments, the comparing the respective outputs includes comparing the respective outputs provided by the obfuscated design and the original design via a miter circuit.

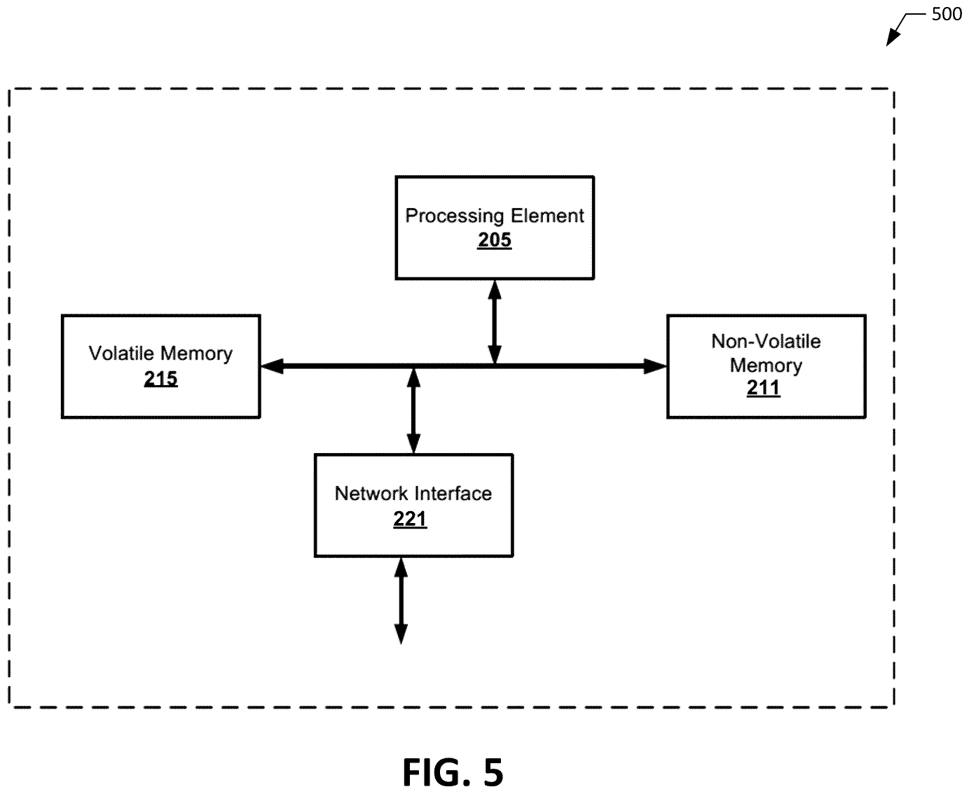

In an example embodiment, an apparatus for performing the method 400 of FIG. 4 above may include a processor configured to perform some or each of the steps (402, 404 and/or 406) described above. The processor may, for example, be configured to perform the steps (402, 404 and/or 406) by performing hardware implemented logical functions, executing stored instructions, or executing algorithms for performing each of the operations. Alternatively, the apparatus may comprise means for performing each of the operations described above. In this regard, according to an example embodiment, examples of means for performing steps 402, 404 and/or 406 may comprise, for example, the processor and/or a device or circuit for executing instructions, executing operations, or executing an algorithm for processing information as described above. In various embodiments, an apparatus for performing the method 1400 may correspond to apparatus 500 illustrated in FIG. 5.

### B. EXEMPLARY TECHNICAL IMPLEMENTATION OF VARIOUS EMBODIMENTS

Embodiments of the present disclosure may be implemented in various ways, including as computer program products that comprise articles of manufacture. Such computer program products may include one or more software components including, for example, software objects, methods, data structures, and/or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid state drive (SSD), solid state card (SSC), solid state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for, or used in addition to, the computer-readable storage media described above.

As should be appreciated, various embodiments of the present disclosure may also be implemented as methods, apparatus, systems, computing devices, computing entities, and/or the like. As such, embodiments of the present disclosure may take the form of a data structure, apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises a combination of computer program products and hardware performing certain steps or operations.

Embodiments of the present disclosure are described with reference to example operations, steps, processes, blocks, and/or the like. Thus, it should be understood that each operation, step, process, block, and/or the like may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some exemplary embodiments, retrieval, loading, and/or execution may be performed in parallel such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

FIG. 5 provides a schematic of an exemplary apparatus 500 that may be used in accordance with various embodiments of the present disclosure. In particular, the apparatus 500 may be configured to perform various example operations described herein to provides for formal equivalence verification of obfuscated designs. In some example embodiments, the apparatus 500 may be embodied by the formal verification framework 200.

In general, the terms computing entity, entity, device, and/or similar words used herein interchangeably may refer to, for example, one or more computers, computing entities, desktop computers, mobile phones, tablets, phablets, notebooks, laptops, distributed systems, items/devices, terminals, servers or server networks, blades, gateways, switches, processing devices, processing entities, set-top boxes, relays, routers, network access points, base stations, or the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

Although illustrated as a single computing entity, those of ordinary skill in the field should appreciate that the apparatus 500 shown in FIG. 5 may be embodied as a plurality of computing entities, tools, and/or the like operating collectively to perform one or more processes, methods, and/or steps. As just one non-limiting example, the apparatus 500 may comprise a plurality of individual data tools, each of which may perform specified tasks and/or processes.

Depending on the embodiment, the apparatus 500 may include one or more network and/or communications interfaces 221 for communicating with various computing entities, such as by communicating data, content, information, and/or similar terms used herein interchangeably that can be transmitted, received, operated on, processed, displayed, stored, and/or the like. Thus, in certain embodiments, the apparatus 500 may be configured to receive data from one or more data sources and/or devices as well as receive data indicative of input, for example, from a device.

The networks used for communicating may include, but are not limited to, any one or a combination of different types of suitable communications networks such as, for example, cable networks, public networks (e.g., the Internet), private networks (e.g., frame-relay networks), wireless networks, cellular networks, telephone networks (e.g., a public switched telephone network), or any other suitable private and/or public networks. Further, the networks may have any suitable communication range associated therewith and may include, for example, global networks (e.g., the Internet), MANs, WANs, LANs, or PANs. In addition, the networks may include any type of medium over which network traffic may be carried including, but not limited to, coaxial cable, twisted-pair wire, optical fiber, a hybrid fiber coaxial (HFC) medium, microwave terrestrial transceivers, radio frequency communication mediums, satellite communication mediums, or any combination thereof, as well as a variety of network devices and computing platforms provided by network providers or other entities.

Accordingly, such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the apparatus 500 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), 5G New Radio (5G NR), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The apparatus 500 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

In addition, in various embodiments, the apparatus 500 includes or is in communication with one or more processing elements 205 (also referred to as processors, processing circuitry, and/or similar terms used herein interchangeably) that communicate with other elements within the apparatus 500 via a bus, for example, or network connection. As will be understood, the processing element 205 may be embodied in several different ways. For example, the processing element 205 may be embodied as one or more complex programmable logic devices (CPLDs), microprocessors, multi-core processors, coprocessing entities, application-specific instruction-set processors (ASIPs), and/or controllers. Further, the processing element 205 may be embodied as one or more other processing devices or circuitry. The term circuitry may refer to an entirely hardware embodiment or a combination of hardware and computer program products. Thus, the processing element 205 may be embodied as integrated circuits, application specific integrated circuits (ASICs), field programmable gate arrays (FPGAs), programmable logic arrays (PLAs), hardware accelerators, other circuitry, and/or the like.

As will therefore be understood, the processing element 205 may be configured for a particular use or configured to execute instructions stored in volatile or non-volatile media or otherwise accessible to the processing element 205. As such, whether configured by hardware, computer program products, or a combination thereof, the processing element 205 may be capable of performing steps or operations according to embodiments of the present disclosure when configured accordingly.

In various embodiments, the apparatus 500 may include or be in communication with non-volatile media (also referred to as non-volatile storage, memory, memory storage, memory circuitry and/or similar terms used herein interchangeably). For instance, the non-volatile storage or memory may include one or more non-volatile storage or non-volatile memory media 211 such as hard disks, ROM, PROM, EPROM, EEPROM, flash memory, MMCs, SD memory cards, Memory Sticks, CBRAM, PRAM, FeRAM, RRAM, SONOS, racetrack memory, and/or the like. As will be recognized, the non-volatile storage or non-volatile memory media 211 may store files, databases, database instances, database management system entities, images, data, applications, programs, program modules, scripts, source code, object code, byte code, compiled code, interpreted code, machine code, executable instructions, and/or the like. The term database, database instance, database management system entity, and/or similar terms used herein interchangeably and in a general sense refer to a structured or unstructured collection of information/data that is stored in a computer-readable storage medium.

In particular embodiments, the non-volatile memory media 211 may also be embodied as a data storage device or devices, as a separate database server or servers, or as a combination of data storage devices and separate database servers. Further, in some embodiments, the non-volatile memory media 211 may be embodied as a distributed repository such that some of the stored information/data is stored centrally in a location within the system and other information/data is stored in one or more remote locations. Alternatively, in some embodiments, the distributed repository may be distributed over a plurality of remote storage locations only. As already discussed, various embodiments contemplated herein use data storage in which some or all the information/data required for various embodiments of the disclosure may be stored.

In various embodiments, the apparatus 500 may further include or be in communication with volatile media (also referred to as volatile storage, memory, memory storage, memory circuitry and/or similar terms used herein interchangeably). For instance, the volatile storage or memory may also include one or more volatile storage or volatile memory media 215 as described above, such as RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like.

As will be recognized, the volatile storage or volatile memory media 215 may be used to store at least portions of the databases, database instances, database management system entities, data, images, applications, programs, program modules, scripts, source code, object code, byte code, compiled code, interpreted code, machine code, executable instructions, and/or the like being executed by, for example, the processing element 205. Thus, the databases, database instances, database management system entities, data, images, applications, programs, program modules, scripts, source code, object code, byte code, compiled code, interpreted code, machine code, executable instructions, and/or the like may be used to control certain aspects of the operation of the apparatus 500 with the assistance of the processing element 205 and operating system.

As will be appreciated, one or more of the computing entity's components may be located remotely from the other computing entity components, such as in a distributed system. Furthermore, one or more of the components may be aggregated, and additional components performing functions described herein may be included in the apparatus 500. Thus, the apparatus 500 can be adapted to accommodate a variety of needs and circumstances.

### C. CONCLUSION

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. A method for providing a functional verification flow of obfuscated designs for circuits, the method comprising:
applying an input sequence to an obfuscated design for an integrated circuit that is formatted in a hardware description language;
applying the input sequence to an original design for the integrated circuit that is formatted in the hardware description language; and
comparing respective outputs provided by the obfuscated design and the original design to determine functional correctness of the obfuscated design.

2. The method of claim 1, wherein the input sequence is a potential key sequence generated during obfuscation of the original design.

3. The method of claim 1, wherein the applying the input sequence to the obfuscated design comprises providing the input sequence to a key checker that compares the input sequence to data stored in a key register.

4. The method of claim 3, further comprising:
applying the input sequence to the obfuscated design in response to a determination that the input sequence corresponds to the data stored in the key register.

5. The method of claim 3, wherein the data stored in the key register is a predetermined key sequence generated during an obfuscation process for the obfuscated design.

6. The method of claim 3, further comprising:
generating a key error value in response to a determination that the input sequence does not correspond to the data stored in the key register.

7. The method of claim 1, wherein the comparing the respective outputs comprises comparing the respective outputs provided by the obfuscated design and the original design via a miter circuit.

8. An apparatus comprising at least one processor and at least one memory including program code, the at least one memory and the program code configured to, with the at least one processor, cause the apparatus to at least:
apply an input sequence to an obfuscated design for an integrated circuit that is formatted in a hardware description language;
apply the input sequence to an original design for the integrated circuit that is formatted in the hardware description language; and
compare respective outputs provided by the obfuscated design and the original design to determine functional correctness of the obfuscated design.

9. The apparatus of claim 8, wherein the input sequence is a potential key sequence generated during obfuscation of the original design.

10. The apparatus of claim 8, wherein the at least one memory and the program code are configured to, with the at least one processor, further cause the apparatus to at least:
provide the input sequence to a key checker that compares the input sequence to data stored in a key register.

11. The apparatus of claim 10, wherein the at least one memory and the program code are configured to, with the at least one processor, further cause the apparatus to at least:
apply the input sequence to the obfuscated design in response to a determination that the input sequence corresponds to the data stored in the key register.

12. The apparatus of claim 10, wherein the data stored in the key register is a predetermined key sequence generated during an obfuscation process for the obfuscated design.

13. The apparatus of claim 10, wherein the at least one memory and the program code are configured to, with the at least one processor, further cause the apparatus to at least:
generate a key error value in response to a determination that the input sequence does not correspond to the data stored in the key register.

14. The apparatus of claim 8, wherein the at least one memory and the program code are configured to, with the at least one processor, further cause the apparatus to at least:
compare the respective outputs provided by the obfuscated design and the original design via a miter circuit.

15. A non-transitory computer storage medium comprising instructions, the instructions being configured to cause one or more processors to at least perform operations configured to:
apply an input sequence to an obfuscated design for an integrated circuit that is formatted in a hardware description language;
apply the input sequence to an original design for the integrated circuit that is formatted in the hardware description language; and
compare respective outputs provided by the obfuscated design and the original design to determine functional correctness of the obfuscated design.

16. The non-transitory computer storage medium of claim 15, wherein the input sequence is a potential key sequence generated during obfuscation of the original design.

17. The non-transitory computer storage medium of claim 15, wherein the operations are further configured to:
provide the input sequence to a key checker that compares the input sequence to data stored in a key register.

18. The non-transitory computer storage medium of claim 17, wherein the operations are further configured to:
apply the input sequence to the obfuscated design in response to a determination that the input sequence corresponds to the data stored in the key register.

19. The non-transitory computer storage medium of claim 17, wherein the data stored in the key register is a predetermined key sequence generated during an obfuscation process for the obfuscated design.

20. The non-transitory computer storage medium of claim 17, wherein the operations are further configured to:
generate a key error value in response to a determination that the input sequence does not correspond to the data stored in the key register.
